(19) United States
(12) Patent Application Publication
(10) Pub. No.: US 2007/0015485 A1
(43) Pub. Date: Jan. 18, 2007

(54) Wireless Media Source for Communication with Devices on Data Bus of Vehicle

(75) Inventors: Jack DeBiasio, Moorpark, CA (US); Roger Alves, Camarillo, CA (US)

Correspondence Address: MCDERMOTT, WILL & EMERY (LOS ANGELES OFFICE), 2049 CENTURY PARK EAST, 34TH FLOOR, LOS ANGELES, CA, 90067-3208, US

(73) Assignee: Scosche Industries, Inc.

(21) Appl. No.: 11/457,302

(22) Filed: Jul. 13, 2006

Related U.S. Application Data
(60) Provisional application No. 60/699,100, filed on Jul. 14, 2005.
(60) Provisional application No. 60/803,807, filed on Jun. 2, 2006.
(60) Provisional application No. 60/803,808, filed on Jun. 2, 2006.

(51) Int. Cl. H05K 11/02

(52) U.S. Cl. 455/345; 455/41.2

(57) ABSTRACT

A wireless audio source integrated into a host bus of a vehicle includes a transmitter module for wirelessly transmitting signals received from a connected portable audio player to a receiver module connected to the host bus. The host bus links to other multimedia devices, such as to the vehicle's radio and speakers, thereby enabling the audio content to be reproduced over the speakers. In one aspect, the user is able to control the volume and related functions of the audio content using the standard radio controls. In other aspects, a portable wireless transceiver is disclosed wherein an occupant of the vehicle can transmit and receive multimedia data to and from a wireless transceiver coupled to the host bus. Multimedia and other devices connected to the host bus can thereby send and receive signals to and from the portable wireless transceiver.

### RELATED APPLICATION DATA

This application claims priority to provisional application Ser. No. 60/699,100 filed Jul. 14, 2005, entitled “Portable Audio Device With A Wireless Connection To A Car Stereo”, provisional application Ser. No. 60/803,807 filed Jun. 2, 2006, entitled “Wireless Audio Source Integrated into Data Bus of Automobile,” and provisional application Ser. No. 60/803,808 filed Jun. 2, 2006, entitled “Wireless Do-It-Yourself Hands-Free Audio Kit For Vehicle Background.” The content of these provisional applications are incorporated by reference as though fully set forth herein.

### BACKGROUND

1. Field

The present invention relates to wireless devices for use with vehicles, and more particularly to a wireless media source capable of communicating with devices on a data bus of a vehicle.

2. Background

With the implementation of numerous sophisticated control and “convenience” systems and features in automobiles in recent years, automobile designers are faced with increasing challenges in integrating all of these systems in a manner that provides functional, structural and operational stability. For example, modern automobiles are equipped with a plethora of electronics relating to engine-control functions, braking, transmission control, suspension features, climate control, audio functions, cellular technology, voice recognition, theft deterrent devices, and the like.

In many cases, these different subsystems by necessity interact with one another. Many engine management functions, for instance, are interrelated and must be wired together electronically in some fashion. Numerous electronic control mechanisms exist in automobiles today. These control mechanisms sense vehicle measurements like engine revolutions-per-minute (RPM), vehicle speed, engine temperature, etc., and make determinations based on these measurements. The control mechansims may thereafter send various commands to actuators to make adjustments in the engine or to notify the driver via the control panel on the dashboard of a potential problem. The various electronic control mechanisms routinely transmit and receive information between themselves. For example, the engine must communicate the engine speed to the transmission for the two subsystems to interact.

As the level of sophistication of these automobiles continues to increase, automobile manufacturers have been faced with an increasing dilemma of providing a seamless integration of devices and control systems within their vehicles. Simply connecting discrete devices together using standard wires and connectors has become impractical. In the case where the components of a modern security system, for example, are integrated together, the splicing of wires and the use of connectors to integrate the components of such a system results in an unacceptable level of complexity, a greater than acceptable consumption of power through heat lost in the resistance of the wires, and an increased probability of a malfunction or technical problem. This level of complexity in the event of a malfunction would also lend it difficult for a mechanic to locate and fix the problem within a reasonable period of time.

In some new vehicles, electronic sensors are provided that sense a potential collision. The electronic sensors in these vehicles need to interface with the suspension control system so that the automobile suspension tightens up in anticipation of an impending collision. Other safety features, such as airbags and newly designed seatbelts, may need to contain sensors that are electronically coupled to each other and to other devices. Door locks, remote control devices, moon roof control, lighting, security, seat control, heated seats, climate controls, electronic windows and the attendant requirement of their integration with various devices are additional examples of the added complexity of modern vehicles, particularly as new devices, features, and functionality are progressively added.

This necessity for the exchange of data among the various subsystems of a modern vehicle has caused vehicle manufacturers to seek improved means to integrate devices together in a more seamless and less complex manner. These efforts eventually led to the adoption of numerous bus standards for electronically connecting devices in the vehicle together. In short, standardized electrical busses were designed to connect related devices together. The use of busses has numerous advantages in the context of vehicle electronics, including, for example, a standardized and organized protocol for the conduction of signals, lower power dissipation, hierarchical multiplexing for ensuring that high priority actions (e.g., safety-related functions) take precedence over lower priority ones (e.g., multimedia functions), the reduction or elimination of costly and power-consuming wires and connectors by virtue of smaller integrated bus conductor traces and the corresponding simplification of the connections, among other attributes.

Different classes of exemplary automotive busses exist. As of this time at least six different classifications have either been implemented or proposed in the literature. Class A is a multiplexing wiring system applied to automobiles. While traditional wiring may not be altogether eliminated, wiring can be substantially reduced in Class A busses by employing the well-known technique in electronics of enabling, through one of several known multiplexing schemes, the transmission and reception of multiple signals over the same bus. Class B is another multiplex-based wiring system that is predicated on the concept of transmitting data between nodes, rather than stand-alone devices (For example, an automobile speaker may be associated with a node, the node having common properties of other nodes in the bus system). Class C is yet another multiplex-based wiring system which reduces wiring by transmitting data at a higher frequency. Emissions/Diagnostic busses are another class which relate to the integration of vehicle emissions devices or Diagnostic devices.

Most recently, consumers have desired increased capability for using multimedia devices in vehicles or having the multimedia devices integrated into vehicles. The desire for integration of vehicle devices encompasses the arena of continuously integrating increasing numbers of multimedia devices. In anticipated newer automobiles, for instance, speakers may be connected not only to their respective radio, CD, cassette and amplifier systems, but also to devices which enable transmission of cellular telephone signals over the speakers, or to a digital audio player or an in-vehicle DVD player. For vehicles equipped with the latest wireless telephone convenience features, the audio from the speakers may need to be muted when an incoming cellular call arrives.

Mobile Media busses are designed more specifically for mobile media equipment, such as cellular telephones and GPS systems. X-by-Wire busses is a term for bus types that enable electronic systems to be added to and integrated with the vehicle to enhance and replace tasks that were previously handled using mechanical systems. (For more information on vehicle bus types, see “Automotive Buses” at http://www.interfacebus.com/Design_Connector_Automotive.html). Mobile Multimedia Link™ is another standard developed for use with multimedia-type devices.

One recent bus scheme that has been developed for use in vehicles is based on the transmission of light between fiber optic wires. Developed by MOST Corporation, MOST® is a standard that defines a multimedia point to point network. MOST® was designed to provide a bus/networked based solution for automotive multimedia. The physical layer of the MOST® standard uses plastic fiber optic cabling. The MOST® bus may be organized in a variety of topologies; most notably, a star, daisy-chain, or ring configuration. The specifications of MOST® define not only the physical layer, but also the Application, Network, and MAC layers of the OSI model. MOST® uses an electrical-to-optical converter to transmit multimedia optical signals over its network, as well as an optical-to-electrical converter to transmit and receive electrical signals from the various multimedia components to which it is attached. Further information and specifications for MOST® may be found at MOST Corporation's website (www.mostnet.de).

The Most® specification is suitable to combine a number of multimedia devices on one bus. Such devices may include, for example, an integrated cellular phone, digital radio, portable laptop computer, amplifiers, GPS navigational system, CD changer, speakers, equalizers, video display, and the like.

With the continued progression of vehicles that employ or use multimedia devices, MOST® and other multimedia-based bus schemes (e.g., Mobile Multimedia Link (MML)) have advanced the state of the art by providing flexible and more cost-effective mechanisms to couple together multimedia devices.

An increasingly desirable and popular entertainment feature for consumers is the use of a mechanism that connects to portable audio devices, such as to music players using MPEG1 layer 3 audio compression like Apple's iPod or similar players, to play music over the stereo speakers of their vehicle. Consumers desire a solution that produces high quality sound and uses a minimum amount of extraneous equipment to minimize the negative aesthetic effects associated with cumbersome wiring in the vehicle's interior. Another popular entertainment feature would be to use various portable media devices, such as laptop PCs, PDAs, GPS devices, gaming devices, and the like, to interact with other devices integrated in a vehicle.

Various approaches to play audio sourced from a portable audio player have been implemented or proposed in the literature. In one approach, as shown in U.S. Patent Application Publication No. US 2005/0049009 A1 filed by Yamamoto, a portable audio player is connected to a “plug” device that fits into a standard cigarette lighter of a vehicle for supplying power to the plug transmitter. The plug device processes the signal from the portable audio player and retransmits it using a wireless transmitter as an AM or FM radio wave in the frequency spectrum of the vehicle's radio. The radio wave is received by the vehicle's standard radio antenna, and the music from the portable audio player is played using the vehicle's radio through its speakers. In another approach, as disclosed in U.S. Patent Publication No. US 2003/0053378 A1 filed by Lovin et al., a portable device (such as a cell phone or personal audio player) containing a wireless transceiver transmits (or receives) signals to or from a second wireless transceiver contained in a cylindrical apparatus. The cylindrical apparatus processes the received signal and retransmits it over the FM radio spectrum. The cylindrical apparatus is connected directly to the vehicle's radio by a coaxial cable and provides audio through the radio over a designated FM frequency.

These approaches have drawbacks. For example, the quality of the audio is significantly less than the near-CD quality of most portable audio players. Both the FM and AM frequency bands lack the dynamic range to reproduce the higher quality sound associated with a portable music player. Further, traditional AM and FM frequency bands are susceptible to significant interference, both from physical obstacles that interfere with the transmission of radio waves and from other FM and AM sources transmitting at or near the same frequencies. In short, sound quality is compromised.

In addition, both approaches require a direct connection to the radio itself, either through the vehicle's antenna (as in Yamamoto) or through a coaxial input (as in Lovin). Thus, for vehicles that implement a data bus to connect multimedia devices together, neither prior art approach can take advantage of other related devices connected to the bus. For example, in the case of a portable music player using prior art methods, the player would not have access to or the ability to interface with any other devices on the bus, such as a discrete equalizer, audio amplifier or an integrated audio recorder for recording the music for future playback. In the case of a cellular telephone, the phone would not have access to a discrete microphone on the bus to enable an interface to allow the driver to speak into the microphone and thereby transmit voice back to the caller via the cellular telephone. In addition, the device disclosed in Lovin requires a hardwired connection to the radio itself, resulting in greater complexity and still greater difficulty in installing.

Other prior approaches rely on connecting the wireless receiver directly to the radio, either through an auxiliary input or through the left and right stereo channels. These approaches contain the same limitations in that they cannot interface with any other device on the bus.

In addition, a desirable all-purpose mechanism for enabling any portable multimedia device to wirelessly interact with the bus and its connected components would add great flexibility to add features and components on the bus. At present, discrete portable media devices cannot interface with any of the multitude of bus features and functions available on the various bus standards. Thus, presently, a vehicle occupant can only use devices that have been previously integrated within the vehicle at the time of manufacture.

As a result, a need exists in the art for providing an apparatus that produces high quality audio and that can interface with, as appropriate, other multimedia devices on the vehicle bus. A need further exists to provide a variety of discrete multimedia devices, unattached to the bus, with the ability to interact with other devices connected to the bus and integrated within the vehicle.

### SUMMARY

The present invention includes a transmitter module for receiving audio content from a portable music player, wirelessly transmitting that content to a receiver module connected to a host bus via an appropriate interface, wherein the receiver module can communicate with any suitable device interfaced with the host bus, including the speakers for high quality audio reproduction.

The present invention further includes a first portable wireless transceiver for connecting to and interfacing with a variety of multimedia devices on the bus, and a second transceiver coupled to the bus configured to wirelessly interface with the first portable wireless transceiver, such that a multitude of portable media devices external to the vehicle can be connected to the first portable wireless device and configured to interact with any appropriate device connected to the bus.

In one aspect, a wireless audio source for transmitting audio content to a receiver coupled to a host bus integrated into a vehicle includes a wireless transmitter module configured to interface with an output of a portable audio player, to receive an audio signal from the portable audio player, and to wirelessly transmit the audio signal using a predetermined wireless protocol, wherein the transmitted audio signal is received by a wireless receiver coupled to an interface with the host bus for transmitting the audio data onto the bus, and wherein the wireless receiver is configured to receive the transmitted audio signal using the predetermined wireless protocol and to recover audio data in the signal for playback on speakers in the vehicle.

In another aspect, a wireless audio source integrated into a host bus of a vehicle includes a transmitter module including one or more input jacks for receiving an audio signal from a portable audio player, circuits for converting the audio signal into a first format suitable for wireless transmission, and an antenna for transmitting the first formatted audio signal using a predetermined wireless protocol, as well as a receiver module connected to the host bus and comprising an antenna for receiving the first formatted audio signal and circuits for converting the first formatted audio signal into a second format suitable for transmitting data in the first formatted audio signal into a second format for transmission onto the host bus.

In yet another aspect, a wireless audio source integrated with a host bus of a vehicle includes wireless transmitter means for transmitting an audio signal from a portable audio player to a receiver module, wireless receiver means for transmitting the audio signal to the host bus, and playback means for reproducing the audio content over speakers in the vehicle.

In still another aspect, a method for reproducing audio on speakers in a vehicle using signals transmitted over a host bus in the vehicle includes wirelessly transmitting, from a transmitter module, audio content received from a portable audio player connected to the transmitter module, wirelessly receiving, from the transmitter module, the audio content at a receiver module, transmitting, over a bus interface of a host bus in the vehicle, a signal including the audio content onto the bus, the signal addressed to nodes coupled to respective interfaces of speakers on the bus, and reproducing the audio content over the speakers.

In a further aspect, a wireless apparatus for enabling a portable media device to communicate with a device connected to a host bus integrated into a vehicle includes a first portable wireless transceiver configured to connect with the portable media device using a wired connection, and a second wireless transceiver coupled, using a wired connection, to an interface on the host bus, wherein the first portable wireless transceiver receives data from the portable media device and sends the data including an address of the device, using a short-range wireless protocol, to the second wireless transceiver; and wherein the second wireless transceiver receives the data using the short-range wireless protocol and transmits it onto the bus to the device.

In still a further aspect of the invention, a portable wireless apparatus for controlling devices wired to a host bus of a vehicle includes a portable remote control including a first wireless transceiver configured to transmit and receive data to and from a second wireless transceiver coupled to an interface on the host bus, wherein the second wireless transceiver is configured to transmit first signals received wirelessly from the first wireless transceiver to one or more of the devices, and wherein the second wireless transceiver is configured to wirelessly transmit second signals received from at least one of the devices to the first wireless transceiver.

In yet a further aspect of the invention, a system for wirelessly communicating with devices coupled to a vehicle host bus includes first transceiver means for wirelessly transmitting first signals including first data and for wirelessly receiving second signals including second data, second transceiver means for wirelessly transmitting the second signals including the second data to the first transceiver means and for wirelessly receiving first signals comprising first data from the first transceiver means, host bus interface means for connecting the devices to the host bus, and device communication means for transmitting third signals including third data over the host bus to the second transceiver means, and for receiving fourth signals including fourth data over the host bus from the second transceiver means.

It is understood that other embodiments of the present invention will become readily apparent to those skilled in the art from the following detailed description, wherein it is shown and described only various embodiments of the invention by way of illustration. As will be realized, the invention is capable of other and different embodiments and its several details are capable of modification in various other respects, all without departing from the spirit and scope of the present invention. Accordingly, the drawings and detailed description are to be regarded as illustrative in nature and not as restrictive

### BRIEF DESCRIPTION OF DRAWINGS

Various aspects of an accessory connector are illustrated by way of example, and not by way of limitation, in the accompanying drawings, wherein:

FIG. 1 shows an exemplary bus system of a vehicle integrated with a portable music player in accordance with an embodiment of the present invention;

FIG. 2 shows a description of the wireless source and receiver coupled to the host bus in accordance with another embodiment of the present invention.

FIG. 3 is a block diagram of a vehicle bus interfaced with a plurality of multimedia devices in accordance with an embodiment of the present invention.

FIGS. 4A and 4B show a conceptual illustration of an exemplary method of streaming wireless audio to a receiver at a vehicle bus interface in accordance with an embodiment of the present invention.

FIG. 5 shows a wireless audio player connected to a transmitter module for transmitting audio content to a receiver module in accordance with an embodiment of the present invention.

FIG. 6 shows a vehicle dashboard with a host bus and connected receiver module in accordance with an embodiment of the present invention.

FIG. 7 is an illustration of a portable wireless transceiver connecting a PC laptop to various devices connected to the vehicle host bus in accordance with an embodiment of the present invention.

FIG. 8 is a portable wireless transceiver connected to a portable device in accordance with an embodiment of the present invention.

FIGS. 9A and 9B show a plurality of devices on a vehicle host bus and portable wireless transceivers in accordance with an embodiment of the present invention.

### DETAILED DESCRIPTION

In one embodiment, the present invention relates to the use of a vehicle bus for connecting related components, such as multimedia components, together. More specifically, one aspect of the present disclosure is directed to a portable audio player which is coupled to a wireless transmitter module via a cradle apparatus or other connection as shown herein. The wireless transmitter module contains processing circuitry to convert the audio output from the portable audio player into a form suitable for transmission over the selected wireless transmission protocol. The wireless transmitter module also includes a transmitter device for transmitting over-the-air signals.

In addition, a wireless receiver or wireless transceiver is coupled to a vehicle bus. The wireless receiver receives the audio, extracts the audio content from the signal, and transmits it onto the bus using the signaling format required by the bus. The signal may then, for example, be carried along the bus to the speakers of the automobile, which are similarly coupled to the bus. Intervening equalization and amplifier circuitry may also reside on the bus for increasing the quality and boosting the transmission power of the audio signal. In this manner, the apparatus of the present invention can transmit signals directly from the portable device to the vehicle bus, interface with any necessary circuitry or devices resident on the bus, and be transmitted directly through the speakers without the necessity of using the frequency spectrum of the vehicle radio to transmit signals. The present invention provides for a much higher audio dynamic range than existing solutions, and is able to interface with any suitable multimedia device resident on the vehicle bus.

The standard of wireless transmission that may be used in the present invention can be any suitable type, including one of the several wireless standards available. Examples include Bluetooth™, HomeRF™, the various IEEE 802.11 Wi-Fi standards, Skinplex™, Ultra-Wideband (UWB), IEEE ZigBee, Ambient Network, etc.

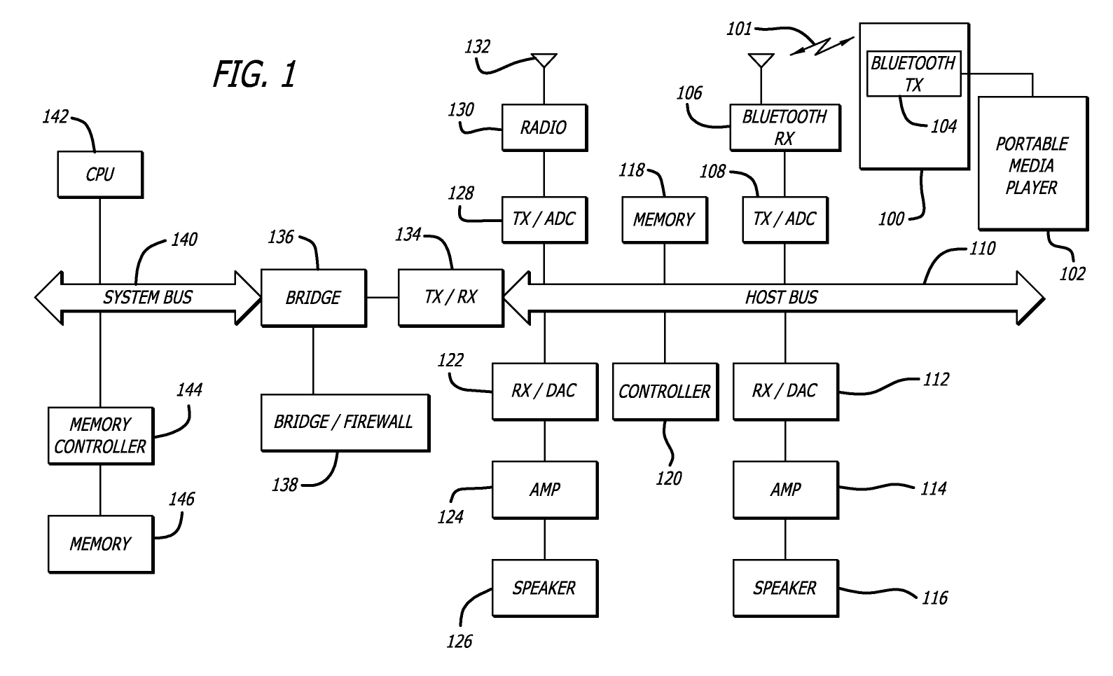

FIG. 1 shows an exemplary bus system of a vehicle integrated with a portable music player in accordance with an embodiment of the present invention. A system bus 140 is shown, which can be used either to pass messages along to different bus systems, or to connect to various core vehicle subsystems. Such subsystems may include, by way of example, the ignition switch, hood, trunk, window and door switches, suspension system, airbags, security system, engine control, transmission control, and others. Central processing unit 142, in conjunction with memory controller 144 and memory 146, may arbitrate which signals are transmitted on the system bus, and may also arbitrate which signals may be sent and received across bridge 136 to and from host bus 110. For example, memory 146 may contain information regarding which transmissions are higher priority transmissions (e.g., tightening the vehicle's suspension system as a result of an impending collision), versus lower priority transmissions (e.g., multimedia-based transmissions on the host bus 110).

In addition to routine bus arbitration functions, CPU 142 uses these data and routines stored in memory 146 to determine which transmissions take precedence. In the example above, the CPU 142 may transmit to the bridge 136 a signal to prevent devices having addresses resident on the host bus 110 from transmitting signals to the system bus 140, thereby freeing the system bus 140 for a higher-priority function. CPU 142 may also enable a transmitting device from the system bus 140 to send messages to devices on the host bus 110, and vice versa.

Further included is transmitter/receiver module 134, which is designed to transmit signals from host bus 110 that are addressed to devices on system bus 140. Module 134 is also used to receive signals from bridge 138 for transmission to an appropriate device on host bus 110.

FIG. 1 also includes a firewall 138, in this example coupled to the bridge, to prevent unauthorized intrusion from other entities into the subsystems coupled to the system bus 140. The firewall 138 may be programmed to maintain security with respect to the subsystems coupled to the system bus 140 and host bus 110. Alternatively, a separate firewall (not shown) may be used in conjunction with the host bus 110 to prevent unauthorized intrusions by other systems or users unrelated to the vehicle of the multimedia systems coupled to the host bus 110. Some form of firewall protection is particularly important where, as here, wireless networks on the host bus are involved.

Depending on the bus standard employed, the host bus 110 need not necessarily include only multimedia-class devices, but may also include other vehicle subsystems.

Attached to host bus 110 is a controller 120 which may arbitrate the bus transmissions based on data or code contained in memory 118. The method of arbitration is generally specific to the bus standard used. For example, where a bus based on a multiplexing scheme is employed, the controller 120 may multiplex the various subsystems so that each subsystem performs a transmission or receives data at a specified time slot or frequency channel. The specific protocols used in connection with the host bus 110 are design details not specific to the present invention. In the present example, it is assumed that host bus 110 constitutes a set of electrical conductors that carry baseband digital data to and from its various subsystems.

FIG. 1 also shows a vehicle radio 130 having a standard antenna 132 for receiving transmissions such as FM/AM transmissions. Other configurations may involve the receipt of satellite radio transmissions. The radio 130 is coupled to generic transmitter and analog-to-digital converter (TX/ADC) 128, which contains the circuitry necessary to transmit the radio signal onto the bus in a signaling format conducive to the particular host bus standard. In this example, TX/ADC 128 would include an analog-to-digital converter for converting the analog audio signals into digital signals for transmission on the bus. TX/ADC 128 also includes an appropriate bus interface controller which is used to interface with the particular bus protocol.

Further shown in FIG. 1 are two exemplary speakers 116 and 126. The speakers are coupled, respectively, to the host bus 110 by amplifiers 114 and 124, and transmitter circuits 112 and 122. In the case of the vehicle driver playing FM stereo on the radio 130, the digitized stereo signals would be received by the speakers 116 and 126 via receivers/digital-to-analog converters RX/DAC 112 and RX/DAC 122. RX/DAC 112 and RX/DAC 122 include digital-to-analog converters for reconverting the audio signals into analog form. Amplifiers 114 and 124 then boost the signal to its desired level for reproduction on speakers 116 and 126.

Transmitting module 100, which includes in this embodiment Bluetooth transmitter 104, is further described. Transmitting module may be powered through its own battery power source, a hardwired connection to a contact point in the vehicle leading to the vehicle battery, or through the cigarette lighter, etc. Transmitting module 100 is connected to portable media player 102. For the purposes of this embodiment, it will be assumed that portable media player 102 constitutes a portable music player. Portable music player 102 may be a standard music player using mp3 or other audio compression techniques (e.g., wma, etc.), such as Apple Computer's iPod™, a Rio™ mp3 player, or the like. Portable music player 102 may be connected to the transmitting module 100 through its output headphone jack to a dual stereo input resident on the transmitter. In some embodiments, transmitting module 100 contains a cradle for inserting the portable music player, or a set of clips for attaching the portable music player to the transmitting module 100. The physical configuration of the transmitting module 100 is a matter of design detail, and those of skill in the art may contemplate different means for connecting or affixing the portable music player 102 to the transmitting module 102. Alternatively, in some implementations, the portable music player may not be physically affixed to the transmitting module 100. Instead, it may be merely connected to the module 100 by a wire to enable transmission of audio to the module 100. In still other configurations, another output on the portable audio player, such as a line-out or a multi-pin adapter, may be used in lieu of the headset jack output.

As stated, the transmitting module 100 includes in this embodiment a Bluetooth transmitter 104. The transmitter 104 receives the analog stereo signal from the portable music player 102. The transmitting module 100 includes a Bluetooth transmitter (TX) 104 which uses a modulator, amplifier, and other circuit components to up-convert the baseband analog stereo signals and modulate them onto the Bluetooth (approximate) 2.45 GHz frequency band for transmission via radio waves 101. As is known in the art, the Bluetooth standard divides the frequency band into 79 channels of 1 MHz each, and transmits the signal using a spread spectrum frequency hopping methodology.

At the receiving end, coupled to the host bus 110, is Bluetooth receiver 106. Through known techniques, the receiver 106 recovers and demodulates the received signal from transmitting module 100, down-converting it to an analog baseband signal. The baseband signal is received by the TX/ADC module 108 that digitizes the signal for suitable transmission on the bus. TX/ADC also includes an appropriate bus interface controller which is used to interface with the particular bus protocol. The bus controller 120 authorizes the transmission of the digitized signals onto the host bus 110. The signals are then received by RX/DAC modules 112 and 122 and converted to the analog domain. The signals are then amplified by AMP modules 114 and 124, and the music is reproduced over speakers 116 and 126. In addition, in some embodiments, the controller 120 enables the user to provide volume control and equalization, etc., of the received audio signal by using the available external controls resident on the vehicle's radio 130. For example, the portable media player 102 may include a multi-pin adapter and transmitter 100 may include a Bluetooth receiver wherein control signals are sent from controller 120 to portable media player 102 via the Bluetooth receiver, seeking a request to control various features or functions on the portable media player, such as stop, pause, skip, volume control, and the like. Alternatively or in addition, the controller 120 may simply transmit control signals to the portable media player in response to the use by the vehicle occupant of the various corresponding controls resident on the stereo head unit.

TX/ADC module 108 may, in some embodiments, be integrated into the Bluetooth RX 106. That is, modules 106 and 108 may also be combined into a single physical module. Either the TX/ADC module 108 or the RX/DAC modules 112 and 122 may also contain additional filters (not shown) for reducing any noise that may have been injected into the Bluetooth signal. Similar filters may also be built directly into the Bluetooth receiver 106.

In the example in FIG. 1, the stereo signals are sent directly from the transmitting module 100 to the receiving Bluetooth receiver 106. Bluetooth and numerous existing wireless standards provide for very low interference signals, resulting in the injection of low to negligible amounts of electrical noise in the RF wave 101. The audio content embedded in the signals is then transmitted, via the bus, to the speakers 116 and 126 of the vehicle through the appropriate circuitry. This means that near-CD quality sound can be achieved, unlike previous approaches using transmission over the FM and AM frequency spectrums.

While the example in FIG. 1 uses the Bluetooth™ as the wireless transmission implementation, numerous other existing and future wireless standards may be equally suitable and contemplated by those in the art without departing from the spirit and scope of the present invention.

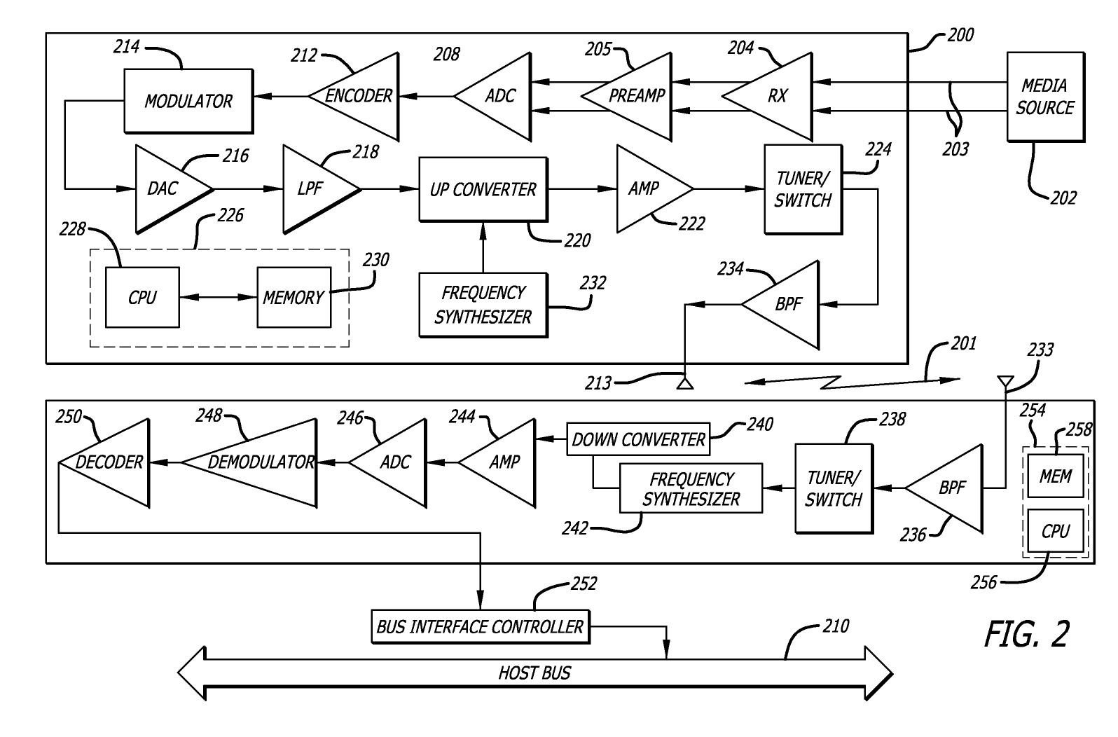

FIG. 2 shows a description of the wireless source and receiver coupled to the host bus in accordance with an embodiment of the present invention. While the principles of the present invention are equally applicable to any suitable wireless technology as described above, the present invention is discussed in the context of the Bluetooth™ standard. It should also be noted that many physical implementations of the Bluetooth™ standard are in fact possible, and the implementation in FIG. 2 is for purposes of illustration only.

Audio source 202 may consist of an audio player, such as an iPod or other audio player for reproducing audio compressed in one of the many numerous formats (MPEG1 layer 3, wma, etc.). Transmitter module 200 contains a path of analog and digital circuits for transmitting the actual signal. Within transmitter module 200 is digital circuit module 226, which contains a central processing unit 228 and one or more memory circuits 230. CPU 228 runs routines contained in memory 230, which may include, for example, routines that implement the Advanced Audio Distribution Profile (A2DP) protocol for transmitting stereo audio content on Asynchronous Connection-less (ACL) channels, and the appropriate encoding protocol (such as, e.g., SBC) for use in transmitting the signal. Memory 230 may also include routines that execute various other Bluetooth profiles and protocols to ensure that, for example, the data is packetized with appropriate headers (such as, e.g., the Media packet header (MP) and the L2CAP header) and error correction, where appropriate, are accounted for, to ensure compliant data transmission. FIG. 2 also shows a receiving module 206 for receiving the transmitted signal and transmitting it to the host bus 210 through bus interface controller 252. In some embodiments, bus interface controller 252 may be a part of receiving module 206.

In the illustration shown, the audio source is connected to the transmitter module 200 through its output stereo headset jacks. (It is also possible to use a line out or other interface on the portable audio player 202 to transmit the signal to transmitter module 200, as discussed above). Lines 203 represent a left and right connection to the transmitter module 200 where each of the two connections 203 contains a baseband analog audio signal. Receiver 204 contains circuitry for receiving the signal, which is then amplified by a pre-amplifier 205. The amplified stereo signals are then fed into an analog-to-digital converter 208, which converts the signals into the digital domain. Thereafter, the digitized stereo signals are encoded using, for example SBC encoding techniques. The SBC encoded digital signal may be sampled at 44.1 KHz or 48 KHz, per Bluetooth standards.

The encoded digital signal is then fed into modulator 214, which may be a Gaussian Frequency Shift Keying (GFSK) modulator. In such a modulation scheme, a digital “one” is represented by a positive frequency deviation of a source signal, and a digital “zero” is represented by a negative frequency deviation. Parameters for such a modulator are known in the art, and may be found in the Bluetooth™ core specification. The modulated signal may then be passed through a digital-to-analog converter 216 for converting the modulated signal into the analog domain. Low pass filter 218 may be used to limit the permissible frequency spectrum of the signal, and hence reduce unwanted noise. The signal is then modulated onto a carrier signal from 2.402 to 2.480 GHz, which represents the spectrum of 79 channels used in the frequency hopping Bluetooth signal. Frequency synthesizer 232 may be used in conjunction with a crystal oscillator to recover the proper signal carrier frequency and reject signals having unwanted or spurious frequencies that may be output from up-converter 220.

The resulting signal is then amplified by amplifier 222, after which certain signal processing may occur relative to the signal by tuner/switch 224. Such processing may include balancing of the signal and segregation of the signal into discrete time slots, etc. The resulting signal may then pass through band-pass filter 234, where unwanted frequencies are rejected. The signal is then transmitted over the air via antenna 213 as a spread spectrum signal using frequency hopping over one or more of the 79 channels, per Bluetooth standards. The timing of this process and the transmission protocols used are, again, governed by the digital circuitry module 226, which module is operatively connected to the relevant front end interface.

The spread spectrum signal 201 is thereafter received by receiver module 206 through antenna 233. Receiver module 206 may be a discrete device in the vehicle with the appropriate hardwired connections to the bus. Alternatively, receiver module 206 may be pre-built and integrated into the vehicle. Like the transmitter module 200, the receiver module contains a digital circuitry module 254 which includes central processing unit 256 and memory 258. Memory 258 stores the routines for implementing the Bluetooth receiver protocols, such as for decoding the signal, reading and removing the packet headers, providing error correction where appropriate, and generally executing the code required to implement the various profiles at the different OSI layers for receiving streamed audio (e.g., AADP, GAVDP, etc.).

The received signal from antenna 233 is filtered via band-pass filter 236 for noise rejection. Thereafter, the signal may be processed using tuning and switch circuitry 236 to account for balancing and switching of the signal as necessary. The resulting signal is then down-converted to baseband using down-converter 240 and frequency synthesizer 242. Frequency synthesizer 242 may include signal recovery circuitry such as a phase/frequency detector, charge pump, phase-locked loop (PLL) and voltage controlled oscillator (VCO). Frequency synthesizer 242 may also include a crystal oscillator for use as a reference frequency.

Following conversion of the signal to baseband, the signal is amplified by amplifier 244 and reverted back to the digital domain using analog-to-digital converter 246. The signal is then demodulated using, for example, a frequency shift keying modulator as is known in the art. The encoded digital signal is then decoded using decoder 250, which may, for example, be an SBC decoder with a sampling frequency of 44.1 KHz or 48 KHz.

The resulting digitized signal is then transmitted to a bus interface controller 252. The bus interface controller 252, which in some embodiments may be part of receiver module 206, governs the timing and format of the transmission of the digitized audio signals onto the bus. The bus interface controller 252 contains a receiving interface for receiving the signal from the receiver module 206, an analog front end for receiving and transmitting signals on the host bus, and conversion circuitry for converting the received digital audio stream into a signal format specific to the bus. A master bus controller (similar to controller 120 in FIG. 1) may perform arbitration and multiplexing functions, and may send and receive signals to and from the bus interface controller 252 over a designated control channel regarding the availability of bandwidth on the bus for the bus interface controller 252 to transmit the audio signals.

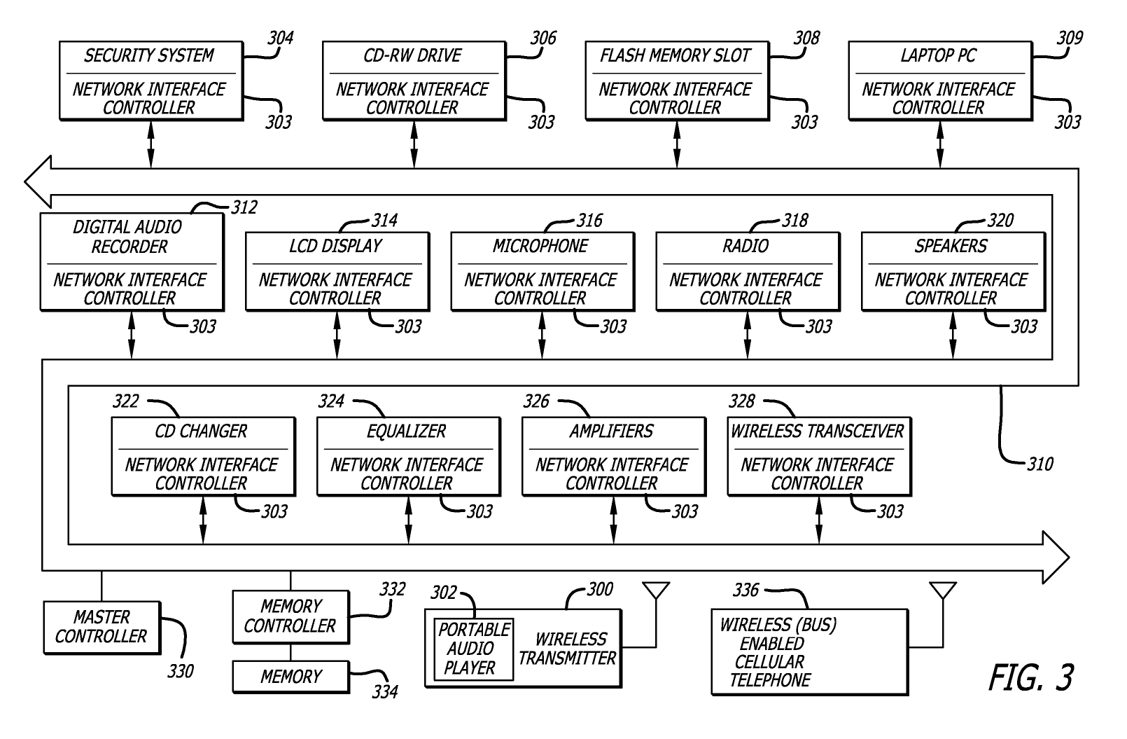

In addition to conforming to the specific bus protocol, the bus interface controller 252 may also send and receive other signals addressed to or from other devices on the bus, such as the volume control of the vehicle's radio, an equalizer, tuner, etc., or other illustrative devices as will be described relative to FIG. 3. Once the audio signal is converted into a format suitable for transmission the bus, the resulting signal containing the audio content may then be transmitted to the bus and sent to the vehicle's speakers through their respective amplifiers and associated circuitry (e.g., digital-to-analog converters, etc.).

Shown in FIG. 3 is a block diagram of a vehicle bus interfaced with a plurality of multimedia devices in accordance with an embodiment of the present invention. In one configuration, the plurality of multimedia devices is integrated into the vehicle. It will be appreciated, however, that in other implementations, one or more devices may be discrete components or other “after market” devices that are hardwired to the bus through an externally available bus connection within the vehicle. One such example may include the laptop PC 309. The illustration in FIG. 3 shows a multimedia-type host bus 310. Connected to the bus via hardwire interfaces are a security system 304, CD-RW drive 306, flash memory slot 308, laptop PC 309, digital audio recorder 312, LCD display 314, microphone 316, radio 318, speakers 320, CD changer 322, equalizer 324, amplifier 326, master bus controller 330, and memory controller 332. The memory controller 332 is connected to memory 334.

Each of the devices 304, 306, 308, 309, 312, 314, 316, 318, 320, 322, 324, 326, and 328 interfaces through the host bus 310 through a plurality of respective network interface controllers 303. The network interface controllers 303 perform substantially the same function as the bus interface controller 252 in FIG. 2. They are essentially slave controllers to master controller 330 which governs bus arbitration; i.e., which device can send which signal at what time or frequency(ies) on the bus. Such arbitration techniques depend on the network type and bus protocol and may include various multiplexing schemes, use of a token, or random transmissions with collision detection, such as that used in Ethernet. The nature of the arbitration depends on the specific bus employed, and is a design detail that may vary without departing from the spirit and scope of the present invention. Each network interface controller 303 may also send and receive signals from the master controller 330 and from other network interface controllers 303 for enabling the respective multimedia devices 304, 306, 308, 309, 312, 314, 316, 318, 320, 322, 324, 326, and 328 to transmit and receive communications to and from one another.

The physical nature of the bus may include any type of conductor, or set of conductors, conducive to the bus standard employed, such as copper wires embedded in one or more circuit boards and disposed about the vehicle to connect to the respective network interface controllers 303. Alternatively, or in addition, the bus may include the use of insulated wiring disposed through the necessary points of contact, fiber optic cabling, or another suitable means of conduction.

Like the bus interface controller 252 in FIG. 2, the network interface controllers 303 also provide a front end analog interface for transmitting and receiving signals to and from the bus, as well as digital logic, processing and conversion circuitry for converting the signals from the various multimedia-type devices into a format compatible with the specific protocol employed by the host bus 310.

Master controller 330 may access the routines and data stored in memory 334 through memory controller 332. Such routines may be used to implement the bus protocols. Memory 334 may also contain a cache of data for storing transmissions from any device on the network. In addition, the respective network interface controllers may also include individual memory banks including cache memory for storing transmissions from other devices.

Wireless transmitter module 300 is connected to portable audio player 302 to provide streaming audio to wireless transceiver 328. Wireless transmitter module 300 may be disposed at any location in or around the vehicle. Wireless transceiver 328 is coupled to the bus via its network interface controller 303. Together, transmitter module 300 and wireless transceiver 328 form a wireless network, enabling transmission of streaming audio to the bus interface. The wireless network may form a piconet or personal area network, and may be constructed using any one of a number of short/intermediate range wireless protocols (e.g., Bluetooth™, HomeRF™, the various IEEE 802.11 Wi-Fi standards, Skinplex™, Ultra-Wideband (UWB), IEEE ZigBee, Ambient Network, etc.). Wireless transceiver 328 includes a receiver circuit (such as that shown in FIGS. 1 and 2) for receiving the streaming audio from transmitter module 300. Wireless transceiver 328 also may include a transmitter for wirelessly transmitting signals to a plurality of wireless devices that employ the same wireless standard, such as, for example, wireless (bus) enabled cellular telephone 336. Wireless transceiver 328 may also include a memory for temporarily storing streamed audio content.

Certain advantages of the present invention become readily apparent by the conceptual diagram of FIG. 3. Unlike previous approaches where an FM transmitter was used or where the wireless receiver was connected directly to the radio, the wireless transmitter 300 of the present invention can access any suitable multimedia device resident on the bus. By way of example, where (as here) the radio 318, equalizer 324 and amplifiers 326 interface directly to the bus 310, and where the user has selected use of the wireless transmitter module 300 for audio streaming, the user can control volume, equalization, and amplification using the controls on the radio 320 or associated dashboard circuitry. The master controller 330 and associated devices will interact over the conduit of the bus 310 to provide audio over the stereo speakers 320 at the volume level and equalization desired by the user.

Furthermore, using the bus scheme as described in FIG. 3, the user may elect to transmit the streamed audio to the CD-RW drive 306 or the digital audio recorder 312 for recording and future playback. The streamed audio may also be provided, via the host bus 310, to the Laptop PC 309 and stored on its hard drive, or to a flash memory device inserted in flash memory slot 308. For ease of use, microphone 316 may be configured to recognize voice commands relating to the various functions that a user may wish to enable, such as recording the streamed audio to one of the devices on the host bus 310. The audio stream may also be stored in memory 334 for subsequent retrieval by one of the devices coupled to the bus.

In an embodiment involving a cellular telephone 336, the user may elect to establish a voice communication channel between telephone 336 and wireless transceiver 328. In the configuration shown in FIG. 3, wireless transceiver 328 also includes a transmitter for transmitting a signal containing the voice information back to telephone 336, providing for full duplex communications. As with wireless transmitter 300, the wireless (bus) enabled cellular telephone can have access to any device on the host bus 310. For example, the user can employ the microphone 316 and vehicle speakers 320 to have a hands free conversation. In addition, unlike previous approaches, the user's cellular telephone 336 can interface with, for instance, the digital audio recorder 312 to record audio conversations. Should the user's cellular telephone 336 include a camera, the picture can be downloaded from the telephone 336 over the piconet to the wireless transceiver 328. The picture can then be displayed on LCD display 314, or stored on laptop PC 309. Most personal area networks, including Bluetooth™, are configured to enable the efficient transmission of both voice and audio (music). Thus, the user can employ a variety of wireless devices to interface with the host bus 310, provided only that they are compatible with the specific wireless protocol of the bus.

In yet another embodiment, the host bus 310 may contain one or more additional transceivers (not shown) for enabling different wireless protocols to coexist on the bus. Provided that the wireless transceivers having different protocols are configured to not interfere with one another (for example, the master controller 330 may, where necessary in light of possible interference, be configured to enable only one transceiver at a time), the host bus 310 may support two or more wireless protocols. This configuration increases versatility and flexibility for a user having portable wireless devices that employ different operating systems and use different wireless standards.

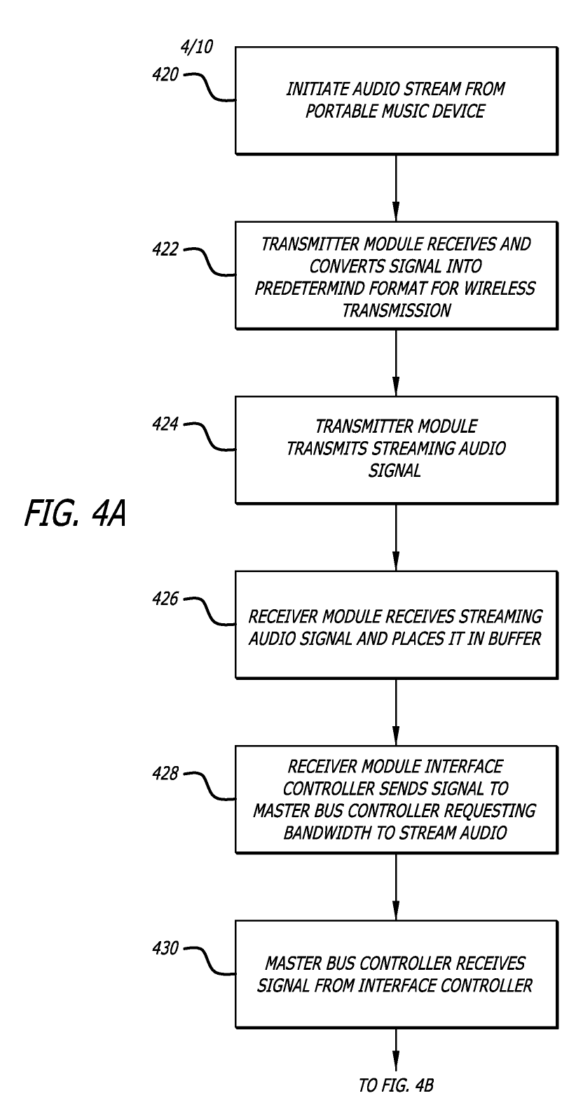

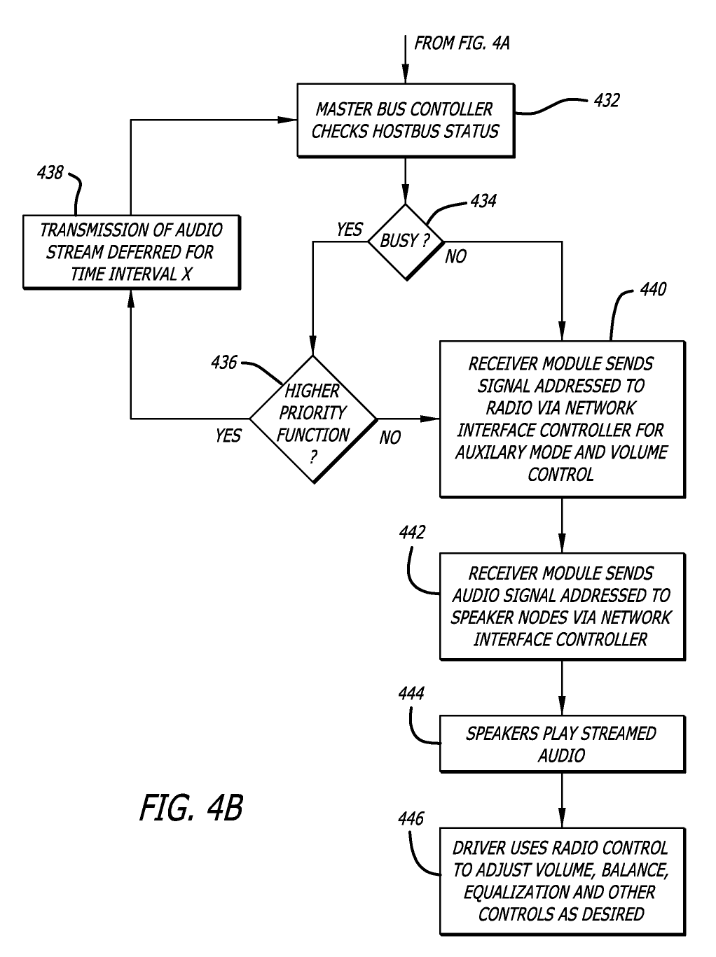

FIG. 4 is a conceptual illustration of an exemplary method of streaming wireless audio to a receiver at a vehicle bus interface in accordance with an embodiment of the present invention. FIGS. 4A and 4B refer to a system using a portable music player having an output operatively attached to the input of a transmitting module, and a receiving module connected to a vehicle bus through an interface controller. As before, the specific wireless standard chosen for the transmitter and receiver are design details that, as one skilled in the art would appreciate, can be implemented without departing from the scope of the present invention.

Referring to FIG. 4A, the process begins by a user initiating the transmission of an audio stream from the portable music device (step 420). In this step, the user may, for example, connect a wire attached to an input jack resident on the transmitter to the output headphone jack of the music player, power the respective devices on, and depress the “Play” button on the music player once the user selects a song or playlist that he or she desires. At that point, the transmitter module receives the audio signal and converts it into a predetermined format for transmission onto the wireless medium (step 422). While this conversion step is exemplified by the illustrations shown in FIGS. 1 and 2, the specific architecture of the transmitting module and conversion circuitry may vary substantially, and naturally depends upon the wireless protocol chosen for use with the device. The transmitting module then wirelessly transmits the audio signal (step 424). The transmitted signals contain within its data fields the destination address of the receiver module.

The receiver module, in turn, receives the streaming audio signal, decodes and demodulates the signal as necessary, and places the data representing the audio content into a temporary buffer (step 426), in preparation to transmit the audio signal onto the bus. The bus interface controller associated with the receiver module (which may or may not be a part of the receiver module, depending on the design) processes the signal into a format suitable for transmission on the bus. In addition, the bus interface controller sends a signal, over the host bus, to the master bus controller, requesting that bandwidth on the bus be allocated in order for the audio data to be sent over the bus (step 428). Depending on the bus type, this signal may be sent over a dedicated control channel or it may be a designated portion of a message over a data channel. It should be noted that, in other implementations, this type of handshaking between the interface controller and master controller may not be necessary, such as in protocols where random transmissions on the bus are permitted (typically with a collision detection mechanism, such as in Ethernet) or where a dedicated channel on the bus has been predetermined for transmissions of this type. In step 430, the master bus controller receives the signal from the interface controller.

Referring now to FIG. 4B, the master bus controller receives the signal from the receiver bus interface requesting allocation of bandwidth and thereupon checks the status of the host bus (step 432). If the host bus is busy (i.e., one or more other devices coupled to the bus are transmitting signals), the master controller may simply wait until the host bus is available before authorizing transmission of the audio data over the bus. Alternatively, the master controller may determine whether the current transmissions relate to a higher priority function (step 434). For example, the system bus may have requested use of the bus, or a vehicle security function may be in progress. Where the master controller determines that the bus is currently allocated to a higher priority function, the master controller may send an ACKNOWLEDGE signal addressed to the receiver bus interface over the control channel indicating that the receiver bus interface should defer transmission of the audio data for a designated time interval X (step 438). In other configurations, the ACKNOWLEDGE signal sent by the master bus controller may simply indicate that the receiver bus interface should remain idle and defer any transmission of audio content until a time when the bus is available, at which point the master bus controller would send a TX OK signal back to the receiver bus interface.

Referring back to the embodiment in FIG. 4B, the master bus controller waits for the designated time interval X to pass, and rechecks the host bus status (step 432). If the host bus is not in use (step 434), the master bus interface sends a TX OK signal to the receiver bus interface. In this embodiment, the receiver module thereupon may send one or more transmissions addressed to the radio bus interface to enable the radio to control settings and volume adjustment of the music stream (step 440). Once this handshaking is complete, the receiver module transmits the audio signal addressed to the interface nodes associated with the vehicle speakers (step 442). Meanwhile, the radio may send and receive signals to both the receiver module and the vehicle speakers (for example, over a control channel) to establish control by the vehicle radio over the reproduction of sound. Other devices resident on the bus, such as an equalizer, may also be used to communicate with the radio, receiver module, and speaker nodes to control settings relating to the playback of the audio on the speakers. The radio may also be configured to implement functions such as pause, stop, skip, rewind, etc., where desirable. This aspect of the present invention enables the driver to use the radio controls to adjust various settings associated with the audio playback (step 446).

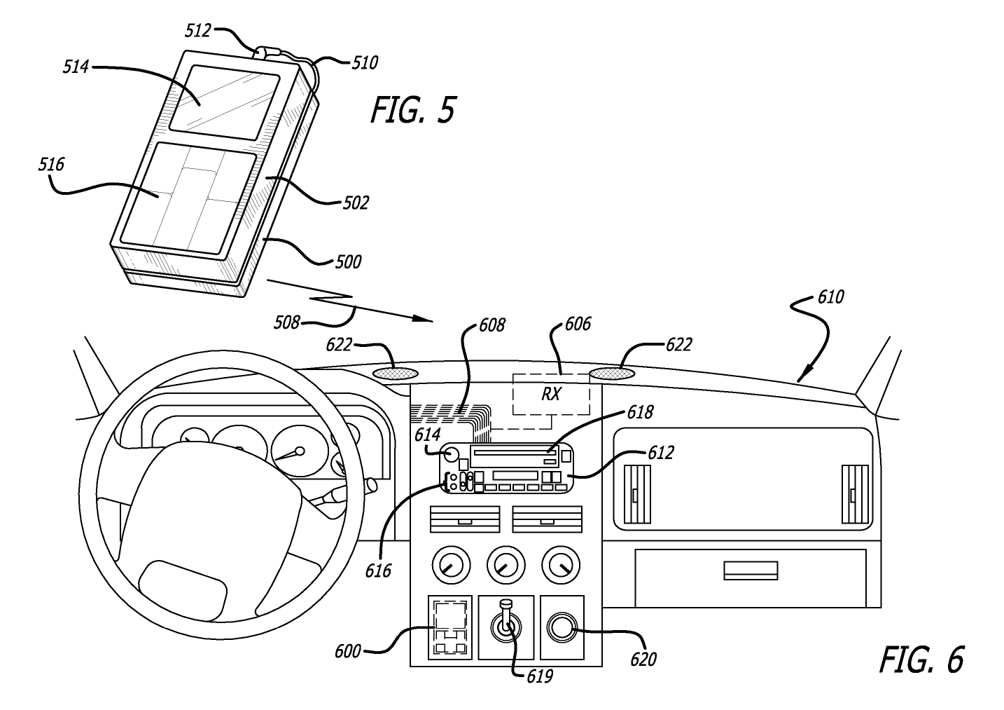

FIGS. 5 and 6 show an example of a wireless audio player connected to a transmitter module for transmitting audio content to a receiver module on a host bus of a vehicle in accordance with an embodiment of the present invention. Referring to FIG. 5, a portable audio player 502, such as an mp3 player, PDA, mobile phone with audio playback capability, etc., is secured on a fitting of transmitter module 500. Portable audio player 502 contains a display 514 for viewing the identity of songs, playlists, etc., as well as various attributes of the songs. Control buttons 516 enable a user to control functions like playback, pause, stop, etc. A wire 510 from the transmitter module 500 connects to the headphone jack 512 of portable audio player 502, Headphone jack 512 on the portable audio player 502 provides an analog baseband stereo output signal which is sent to transmitter module 500. Transmitter module 500 contains any one of a number of known processing circuitry and memory for receiving the audio signal and converting it into a format suitable for transmission over a wireless network, such as HomeRF, IEEE 802.11, Bluetooth, and the like. Transmitter module 500 transmits through an antenna (integrated into the transmitter module 500) a wireless signal 508 containing the audio content. Power may be supplied to the transmitter module 500 using its own battery, using a hardwired connection to a power source in the vehicle, or through a standard cigarette lighter cord connected to the transmitter module 500.

FIG. 6 is a representation of an exemplary vehicle dashboard in accordance with an embodiment of the present invention. The vehicle dashboard 610 includes a radio 614, CD changer 618, a power and volume button 614, and various buttons and sensors 616 for controlling the various functions of the radio. Also disclosed is a “joystick” 619 for enabling a vehicle occupant to control various audio multimedia functions. Conceptually shown in FIG. 6 is a host bus 608 integrated into the vehicle. The host bus 608 is connected to a wireless receiver module 606. The host bus 608, while integrated into the vehicle, may include interface points (on the dashboard or in other portions of the vehicle) for enabling a user to connect other multimedia devices to the bus. In one embodiment, wireless receiver module 608 is integrated into the vehicle. In another embodiment, wireless receiver module 608 is a discrete component that a user can connect to the bus via an appropriate interface located within the vehicle. Where the receiver module is not integrated in the vehicle, the receiver module may also receive power from cigarette lighter 620 or from another hardwire connection to a power source in the vehicle. Dashboard 610 also contains stereo speakers 622.

An antenna (not shown) on the receiver module 606 receives the audio signal 508 from the transmitter module 500 (see FIG. 5). As described with respect to previous embodiments and due to the advantages associated with the bus configuration, a user can elect to reproduce audio from the portable audio player 500 (FIG. 5) and adjust its volume and sound characteristics (e.g., balance, equalization, etc.) using controls 614 and 616. In other embodiments, the user can make these adjustments and control these functions using the buttons on the portable audio player 500 itself. The music from the portable audio player 500 (FIG. 5) is reproduced by speakers 622.

Referring back to FIG. 5, the transmitter module 500 may be a small, portable device which has, in some configurations, a “clip-on” or fitting ability to enable the portable audio player 502 to “piggyback” onto the transmitter module 500. In other embodiments, the transmitter module 500 may be separate from the portable audio player 502, connected only by a wire for transmitting audio data from the portable audio player 502 to the transmitter module 500. In still other embodiments, the transmitter module may be integrated into the dashboard or between the driver and passenger seat of the vehicle, such as shown, for example, by exemplary transmitter module 500. Whether the transmitter module 500 (FIG. 5) is a discrete module for “after-market” use with the vehicle or whether it was integrated into the vehicle at the time of manufacture is a design choice, the implementation of which one skilled in the art will appreciate does not vary from the spirit or scope of the invention.

In another aspect of the invention, a portable wireless transceiver is disclosed. A user of the portable transceiver can transmit and receive data to and from a second transceiver coupled or wired to the host bus (for the purposes of this disclosure, “coupled” or “wired” means either coupled directly, or through intervening circuitry such as, for example, a network interface controller). In turn, the second transceiver may transmit data over the host bus, and devices whose address appears in the data may recognize the signal and process it accordingly. The portable transceiver may constitute a wireless transceiver using any number of short-range wireless technologies as discussed above. Alternatively, the portable transceiver may be part of a bi-directional remote control for controlling, in one device, various functions, such as the vehicle security system and various multimedia devices (such as a CD player, satellite radio, GPS system, etc.).

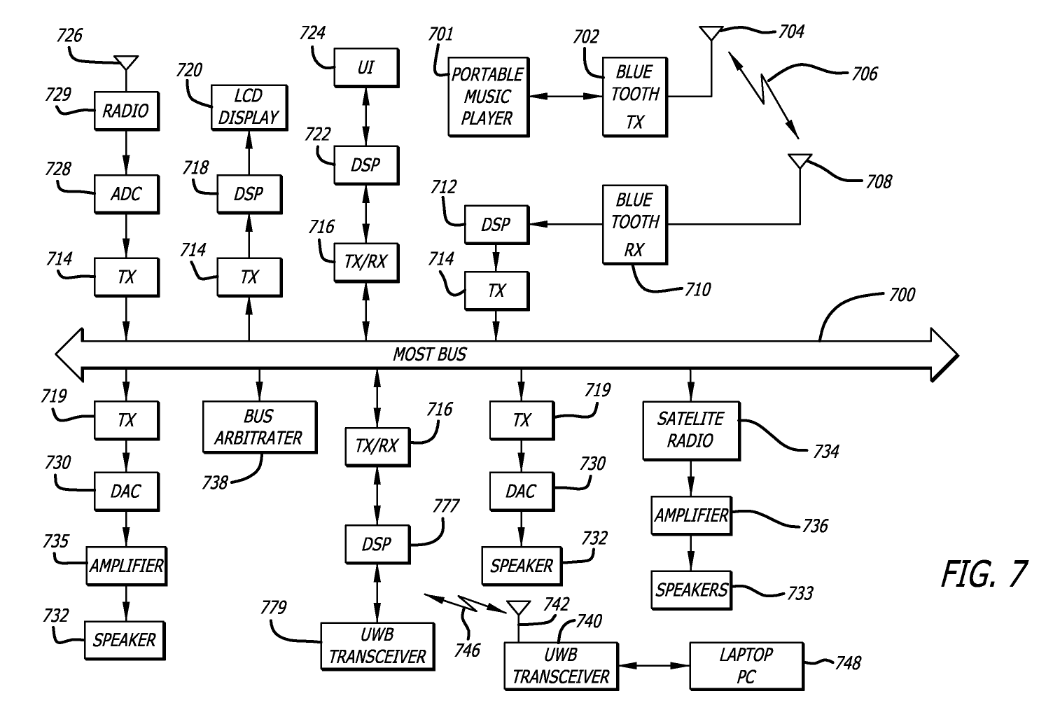

FIG. 7 shows a diagram illustrating an example of the wireless transceiver according to an aspect of the present invention. The portable transceiver 740 uses an Ultra-Wideband (UWB) wireless protocol in this example. Transceiver 740 is coupled, e.g., through a universal serial port (USB) connection, to laptop PC 748. FIG. 7 further shows a MOST bus 700 integrated in the vehicle for enabling the coupling of various multimedia devices. For example, vehicle radio 729 receives FM/AM signals via the vehicle antenna 726, converts the analog signals into an appropriate digital format through analog-to-digital converter (ADC) 728, and then transmits the digital signals through transmitter 714 (which may in some embodiment constitute a network interface controller) onto the MOST bus. The transmitter 714 may append address information to the data to send it to various devices also coupled to the bus. Examples would include transmitters 719 which receives the data from transmitter 714 off the bus (transmitters 719 may constitute network interface controllers), one of which is coupled to digital-to-analog converter (DAC) 730, which receives the data from transmitter 719 and sends it to amplifier 735. The signal is then provided to speaker 732. The other path showing transmitter 719, DAC 730, and speaker 732 performs the same functionality, except in this instance the amplification is performed in the speaker which is connected directly to DAC 730.

In one example, the laptop PC may send wireless signals, via UWB transceiver 740, to an LCD display 720 mounted in the vehicle, such as the vehicle's dashboard or in the rear passenger seat area of the vehicle. In this case, the data is addressed to the display, transmitted wirelessly via antenna 742 through wireless signal 746, received by UWB transceiver 779 and sent through digital signal processor (DSP) 777 to TX/RX unit 716 (which may also include a network interface controller). Thereupon, the signal is transmitted over bus 700 to transmitter 714 associated with the LCD display path. The data is then sent through DSP 718 for processing, and ultimately to LCD display 720.

In addition, a bi-directional user interface (UI) 724 is disclosed (such as a joystick or dashboard control mechanism) in which a vehicle occupant can input commands to be sent over the bus 700 via DSP 722 and TX/RX module 716 to be received by another addressed device, or to be transmitted back to the laptop PC via TX/RX module 716, DSP 777 and UWB transceiver 779, for subsequent over-the-air transmission back to UWB transceiver 740 via wireless signal 746 and antenna 742. The data is subsequently conveyed to the laptop PC 748 through the USB connection.

FIG. 7 further discloses a satellite radio 734 coupled to the bus, with an amplifier 736 and vehicle speakers 733, which may correspond to the same speakers 732. In the manner discussed above, the user of laptop PC 748 may control features and functions of the satellite radio 734 by use of the UWB transceivers 742 and 779.

In addition, a portable music player 701 is shown, which is connected to a Bluetooth transmitter 702. Using an appropriate protocol, such as Bluetooth, audio or stereo content may be streamed via antenna 704 of Bluetooth transmitter 702 and wirelessly sent, as illustrated by wireless signal 706, to a Bluetooth receiver 710. The Bluetooth receiver demodulates and down-converts the signal, and sends the signal to DSP 712, where any appropriate signal processing is performed. The resulting signal (such as a control signal requesting that the devices radio controls take over playback, skip, stop, pause, volume, and other functions of the portable music player 701, or streamed audio) is transmitted over the bus and, through the intervening circuitry shown, to vehicle speakers 732.

In some embodiments, an occupant may use UI 724 to send control signals to the portable music player 701 to enable the radio 729 controls to control the portable music player. In these configurations, for more advanced portable music players, the occupant's use of the vehicle's UI 724 may initiate a handshaking protocol between UI 724 and portable music player 701 to enable the vehicle radio controls or the UI 724 to allow the occupant to control playback via instrument controls on the vehicle dashboard.

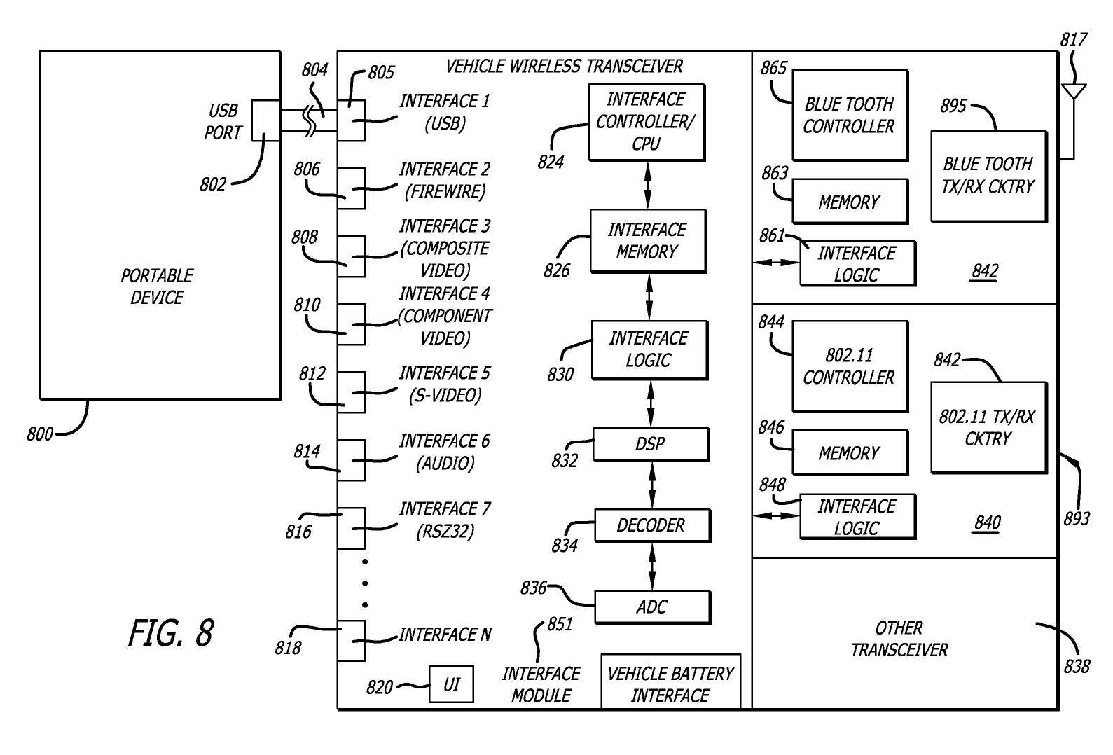

FIG. 8 is a diagram of an illustrative portable wireless transceiver module 822 of the present invention. Transceiver module 822 may be configured in a rectangular version substantially as shown by transmitter module 500 in FIG. 5, or may be another shape. The size of transceiver module 822 will naturally depend on its complexity. In this embodiment, transceiver module 822 represents a versatile and multi-functional unit which contains both numerous interfaces to an illustrative portable device 800 and numerous internal transceiver and numerous internal transceivers, each of which employ a different wireless protocol. In this example, an exemplary portable device 800 (such as a portable GPS unit, audio player, PDA, laptop PC, etc.) is coupled to an interface module 851 contained within transceiver module 800. In this example, interface module 851 is coupled to portable device 800 via portable device 800's USB port 802 and USB cable 804, which connects USB interface 1 (805) of the interface module.

However, for other portable devices 800, interface module 851 advantageously includes FireWire Interface 2 (806), Composite Video Interface 3 (808), Component Video Interface 4 (810), S-Video Interface 5 (812), RCA Audio Interface 6 (814), RS-232 Interface 7 (816), and a plurality of additional interfaces as represented by the dotted lines and arrow pointing to Interface N (818).

It should be noted that the number of interfaces is a design detail and will vary depending on a variety of factors, including the most common interface used, the costs associated with manufacturing transceiver module 822, the desire of small size and portability versus a larger size with greater functionality, etc. A far simpler transceiver module 822 may be envisioned which, for example, employs only a USB port or an RCA connection, etc.

Further to the interfaces 1 through N in FIG. 8 are a number of circuit components in interface module 851 of transceiver module 822 designed to process the signals either received from portable device 8, or received from one of the various transceivers 842, 840, and 838 (described further below). Interface controller/central processing unit 824 is connected to interface memory module 826, which is in turn connected to Interface Logic 830. Further connected to Interface logic are DPS 832, decoder 834, and ADC 836.

The interface controller/CPU 824 runs programs in interface memory 836 to control which interface is being used at a given time. Interface logic 830 and DSP 832 contain the logic necessary to route the signals to their appropriate destination and to process any digital signals to place them in the appropriate digital format for transmission to the portable device 800 or the transceivers 842, 840, or 838, and for reception from the portable device 800 or from the transceivers 842, 840, and 838. Decoder 834 decodes incoming or outgoing signals as necessary for transmission or reception to or from these destinations. If the signal from the portable device 800 is in an analog format, ADC 836 may convert the signal to the digital domain for further processing or transmission. Note that, while the various circuit components 824, 826, 830, 832, 834, and 836 are shown as being connected in serial, any suitable means of organizing and arranging these circuit components may be contemplated by those skilled in the art, and the particular configuration described is not intended to limit the invention.

The interface module is connected to the transceiver portion 893 of transceiver module 822. As denoted by the arrows adjacent interface logic circuits 861 and 848, data is passed to and from the interface module 851. In this example, transceiver portion 893 includes three transceivers; however, it may be contemplated that only one transceiver is used. Each of the transceivers 842, 840, and 838 in this example employ a different wireless standard. Transceiver 842 employs a conventional Bluetooth protocol to transmit and receive signals wirelessly. Transceiver 840, in this illustration, uses an I.E.E.E. 802.11 wireless protocol. Another transceiver 838 may use a separate, unspecified protocol. Thus, if the vehicle's host bus employs more than one type of transceiver, then transceiver module 822 provides greater flexibility and functionality to interface with devices on the bus. For example, if the portable device 800 represents a simple MP3 player, Bluetooth transceiver 842 may be selected. Alternatively, if the portable device 800 represents a DVD player or other high-bandwidth media source, transceiver 840 using an I.E.E.E. 802.11 (n) protocol may be selected.

Referring now to Bluetooth transceiver of FIG. 8, a Bluetooth controller 865, memory 863, and interface logic 861 are present. The Bluetooth controller 865 may run routines in memory 863 in order to implement the Bluetooth protocol as described above. The interface logic 861, either by itself or in conjunction with the Bluetooth controller 865, communicate with the interface logic 830 and interface controller/CPU 824, in order to determine whether the Bluetooth transceiver 842 will be used for transmitting data. Conversely, the Bluetooth controller 865 and interface logic 861 of Bluetooth transceiver 842 may be used to notify the interface controller 824 of the interface module 851 that an incoming signal is being received by Bluetooth transceiver 842. Bluetooth transceiver 842 further includes transmitter and receiver circuitry 895 that implement the Bluetooth standard. In this fashion, data may be passed to and from the interface module 851 and the Bluetooth transceiver 842 for sending and receiving data to and from devices connected to the host bus of the vehicle.

I.E.E.E. transceiver 840 functions in a manner that is substantially similar to that of Bluetooth transceiver 842. I.E.E.E. transceiver includes transmitter and receiver circuitry 842 that implement the particular I.E.E.E. 802.11 standard employed. 802.11 controller 844, in turn, runs code contained in memory 846 to implement one of the 802.11 wireless protocols, and, in some configurations, to determine whether transceiver 840 should be selected in transmitting data. Interface logic 848 interacts with the interface controller/CPU 824 and other circuitry associated with interface module 851 to transmit and receive data to and from interface module 851 and transceiver 840.

Antenna 817 transmits and receives wireless signals to and from one or more transceivers coupled to the host bus of the vehicle. Further, user interface module 820 provides command and control buttons for the transceiver module 822. When activating and operating the transceiver module 822, a user can select different modes of operation, can initiate wireless streaming, can power the device on and off, and can perform other transceiver related functions. Power to the transceiver module 822 can be supplied, for example, by a battery, vehicle cigarette lighter adapter, or a wired connection to a contact point in the vehicle.

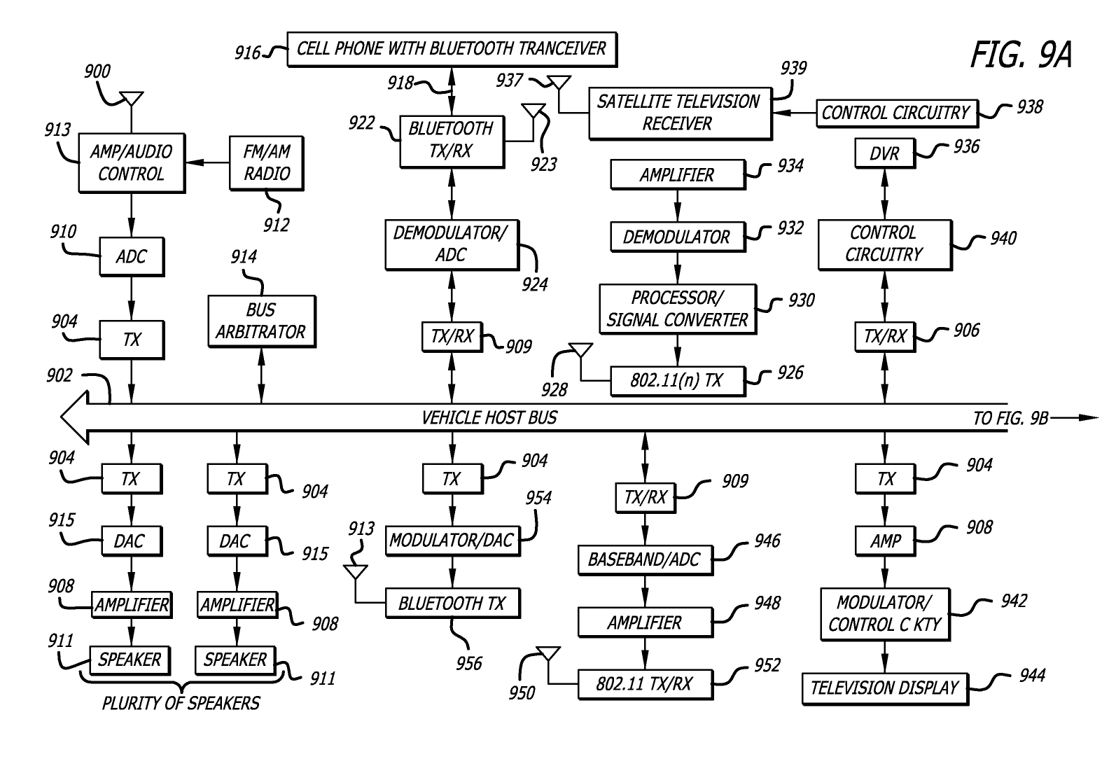

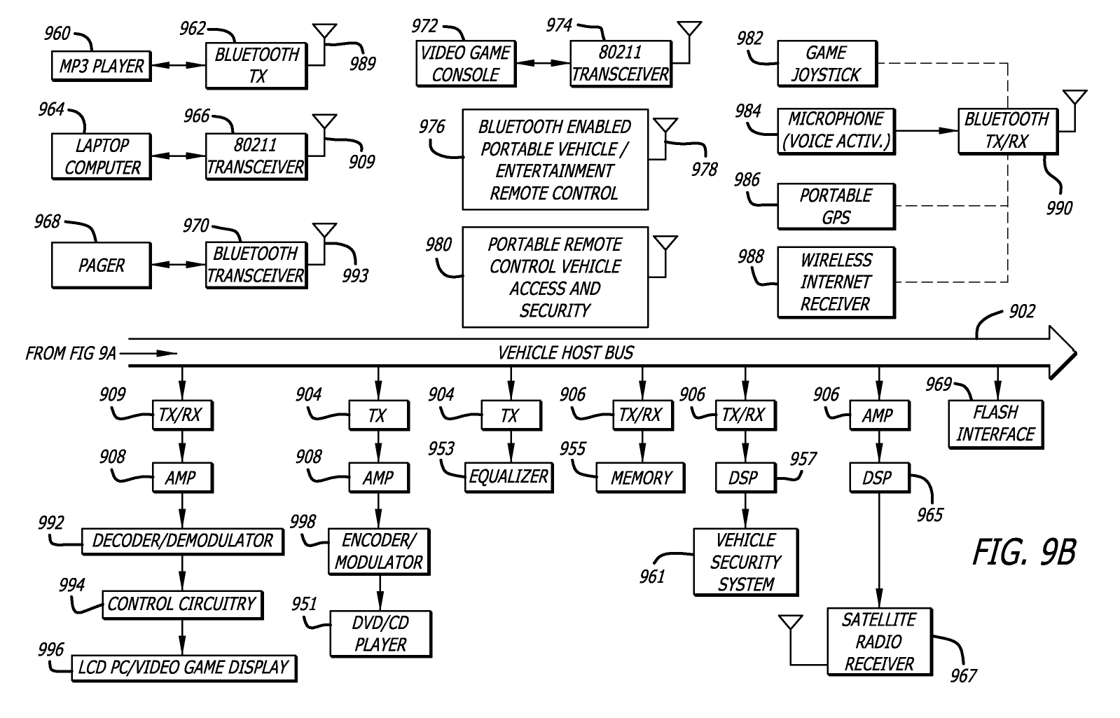

FIGS. 9A and 9B represent an embodiment of the invention using a plurality of devices coupled to the bus and a plurality of portable wireless transmitters, receivers, or transceivers. These Figures show the versatility and capabilities of the portable wireless transceiver of the present invention in terms of its ability to interact with one of several devices on the bus. Referring first to FIG. 9A, a vehicle host bus 902 is shown which is coupled to a plurality of devices. FM/AM radio 912, together with amplifier/audio control module 913 (which may be in some embodiments incorporated into a single device such as a stereo head unit) use vehicle antenna 900 to receive FM/AM broadcasts. These broadcasts are converted to the digital domain by ADC 910, and transmitted, as governed by bus arbitrator 914 and a user interface (not shown), by transmitter 904. Transmitter 904 may include a bus interface controller that, for example, has logic and/or executes code to convert the audio signal to a format suitable for transmission over whatever bus standard is employed. Transmitter 904 may also append an appropriate destination address onto the signal.

Thereupon, the audio signal may be sent over the vehicle bus 902 to the plurality of speakers 911 through transmitters 904, DACs 915, and amplifiers 908, for reproduction of audio over the vehicle speakers 911. In addition, the audio content from FM/AM radio 912 may be transmitted to Bluetooth transmitter 913 through transmitter 904 and modulator/DAC 954, as shown. The signal may then, for example, be wirelessly transmitted to a portable Bluetooth-enabled transceiver module (not shown), which may be connected to an audio recorder (not shown).

Further shown in FIG. 9A is a cellular telephone 916 with Bluetooth transceiver capabilities. The transceiver may send and receive wireless signals using the Bluetooth protocol, via antenna 920, and as shown by the bi-directional arrow 918. The signals to and from cellular telephone 916 are sent to and received by Bluetooth transceiver 922 via antenna 923. Bluetooth transceiver 922 is coupled to the bus through demodulator/ADC module 924 and TX/RX unit 904, which may be a network interface controller for formatting the signal (such as appending address information and error checking coding). The signal may then, for example, be routed to the plurality of speakers 911 for reproduction of voice over the speakers 911. Note the bidirectional arrows between modules 922, 924, and 904. The user may speak into a microphone coupled to the bus, which is converted by a transducer into an audio signal and sent over the bus through Bluetooth transceiver 923, which in turn transmits the wireless audio signal back to cellular telephone 916.

FIG. 9A further includes a Bluetooth transmitter 956, which is attached to modulator/DAC 954, which in turn is connected to transmitter 904, which is connected to the host bus 902. This transmitter 956 can send analog signals wirelessly over its antenna 913 to a portable wireless receiver, which analog signals may be derived from any device connected to the host bus 902. In other embodiments, the modulator/DAC unit 954 may not be needed, and the Bluetooth transmitter 956 can then send digitally encoded signals over-the-air to a wireless destination point.

Also shown in FIG. 9A is a satellite television receiver 939 which receives, under the control of control circuitry 936, a satellite broadcast through its antenna 937. The received signal is amplified by amplifier 934, demodulated by demodulator 932, and further processed by processor/signal converter module 930 to prepare the signal for wireless transmission. At that point, the wireless signal containing the data received by satellite television receiver 939 is transmitted using an 802.11 (n) standardized wireless transmitter, via antenna 928, to the antenna 950 of I.E.E.E. 802.11 (n) transceiver 952. Transceiver 952 contains the circuitry necessary to demodulate the received signal and recover the underlying satellite signal.

The signal received by transceiver 952 is amplified by amplifier 948, and then passed to baseband/ADC module 946, where it is converted to a digital format. Thereupon, transmitter/receiver module 909 converts the digitized signal into a format suitable for the protocol used by the vehicle host bus, appends address information, and transmits over the bus to television display 944, which may be mounted, for example, on the dashboard or on the vehicle's top surface for viewing by passengers in the rear seats. Specifically, the signal is sent to transmitter 904 associated with the television display path, and amplified by amplifier module 908. Next, the signal passes through control circuitry 942 to process the signal and/or convert the signal into an analog format (if necessary) for viewing on television display 944.

Television display 944 may in some configurations contain the necessary control circuitry of unit 942, and may be an LCD panel, plasma display panel, or cathode ray tube display. A bus arbitrator 914 and a user interface on the vehicle dashboard (not shown) may be used to initiate the process of allocating bandwidth on the bus for the receipt of satellite television transmissions for display on television display 944.

Further shown in FIG. 9A is a vehicle-integrated digital video recorder (DVR) 936 connected to the vehicle bus via control circuitry module 940 and TX/RX unit 906. In one illustration, satellite signals placed on the bus through the path of the 802.11 (n) transceiver 952 may be addressed to the DVR unit 936. The signal is received by TX/RX unit 906, which in turn passes the signal to control circuit module 940 to DVR 936. Control circuitry 940, which may in some embodiments be included within DVR 936, processes the signal into a format compatible with the signaling format of DVR 936. It should be noted that DVR 936 can also transmit video and audio signals back over the bus to television display 944, wherein pre-recorded video can be displayed.

FIG. 9B is a continuation of FIG. 9A, showing a second segment of the same host bus 902. A game joystick 982 coupled to Bluetooth transceiver 990 enables a user to wirelessly and interactively control a vehicle-integrated LCD PC/video game display. Alternatively, a vehicle occupant may use a joystick such as that shown in reference 619 of FIG. 6 to control the images on LCD PC/Video Game display. Game joystick 982 includes a controller and, in some cases, a memory for storing games to be played, e.g., by a passenger in the vehicle. The data is transmitted and received over Bluetooth transceiver 990 to Bluetooth transceiver 922 (FIG. 9A), which transmit and receives the game data over vehicle host bus 902 through demodulator/ADC unit 924 and TX/RX module 909. In addition, referring back to FIG. 9B, a portable video game console 972 may be connected to portable wireless Bluetooth transceiver module 974, and signals may be sent and received over antenna 975 back to Bluetooth transceiver 923 (FIG. 9A) for transmission onto or from the bus.

Thereupon, referring back to FIG. 9B, the data sent over the bus is transmitted to TX/RX unit 909 (which may be a network interface controller), amplified by amplifier 908, and decoded and/or demodulated by decoder/demodulator unit 992. The data created by the movement of game joystick 982 is then passed through control circuitry 994, which controls the interactivity of the game being played. Control circuitry 994 may also include a memory buffer for storing information associated with the game, as well as a memory frame buffer for refreshing the LCD PC/video game display 996. Control circuitry unit 994 may also send data back over the bus to be wirelessly transmitted back to control circuitry associated with the game joystick 982, for providing interactivity between the player of the game and the display 996.

Further shown in FIG. 9B is an MP3 player 960, which is coupled to a wireless Bluetooth transmitter 962. The Bluetooth transmitter 962 transmits streamed audio via antenna 989, as described earlier in this disclosure. The signal is received by vehicle-integrated Bluetooth transceiver 922 via antenna 923, and is passed onto the host bus to the plurality of speakers 911. Audio reproduction over the speakers from the MP3 data stored on the MP3 player is then made possible.

Laptop computer 964 is also shown as being attached to an 802.11-compatible portable wireless transceiver 966. The transceiver 966 may transmit and receive data by passing wireless signals to and from transceiver 952 (FIG. 9A). In this manner, portable laptop PC 964 (FIG. 9B) can communicate with any number of devices connected to the bus, such as, for example, DVR 936 (FIG. 9A), television display 944 (FIG. 9A), cellular telephone 916 (FIG. 9A), LCD PC/video game display 996 (FIG. 9B), etc.

Further shown in FIG. 9B is pager 968, which may be a unidirectional or a bidirectional pager. The pager 968 is coupled to portable wireless Bluetooth transceiver 970. Signals may be received by the pager 968 from a standard telephone network. The pager may then transmit these signals over the host bus 902 through, for example, Bluetooth transceiver 923 (FIG. 9A), which may then transmit the signal over the bus to a memory (not shown) resident on the host bus 902. In addition, if pager 968 is a two-way pager, the vehicle occupant may transmit signals to the pager through a user interface on the dashboard and connected to the bus, or from cellular telephone 916 (FIG. 9B).

As another example, Bluetooth-enabled portable vehicle/entertainment remote control 976 constitutes a portable wireless transceiver device that has the capability to control features and functions of the various multimedia devices on the host bus 902. For example, using the Bluetooth enabled remote control 976, a user may be able to adjust the volume of the vehicle stereo, initiate a GPS device connected to host bus 902, adjust settings on television display 944, switch between PC laptop mode and satellite television, initiate dashboard control over an MP3 player connected wirelessly to the bus, and the like. Bluetooth-enabled portable vehicle/entertainment remote control 976 advantageously uses a bidirectional antenna 978 to send and receive signals to and from its associated wireless receiver and wireless transmitter, respectively.

Also shown in FIG. 9B is a portable remote control 980 for controlling vehicle security functions, such as alarm functionality, window and door locks, and the like. Portable remote control 980 contains a wireless transceiver for sending and receiving signals to and from one of the protocol-matched transceivers connected to the host bus 902. In one example, portable remote control module 980 transmits signals in a Bluetooth format to Bluetooth transceiver 923, which, through the intervening circuitry discussed above, transmits the data resident in the signals over the host bus 902 to TX/RX unit 906. The data is sent into a digital signal processor 957 to perform any processing necessary to convert the signal into a format recognizable by the vehicle security system 961. In turn, the vehicle security system 961 can send responses to the remote control by transmitting signals over the bus addressed to Bluetooth transceiver 923 (FIG. 9A), which are then sent to the wireless Bluetooth receiver resident in portable remote control/transceiver 980 (FIG. 9B).

In one embodiment, the functionality portable vehicle/entertainment remote control 978 and portable remote control 980 are integrated together as a single “command and control” remote control for controlling features and functions of many devices attached to host bus 902.

FIG. 9(b) further discloses a portable microphone unit 984 coupled to Bluetooth portable wireless transceiver 990 to enable, for example, a vehicle occupant speaking to another individual on cellular telephone 916 to transmit his voice in a “hands-free” fashion, without using the microphone on the cellular telephone 916. In this example, a user simply speaks in the vehicle and the portable microphone 984 picks up the speech. The portable microphone 984 contains transducer functionality to convert the speech into electrical signals, where the signals are then sent to Bluetooth portable transceiver 990. The signals containing voice data are then received by the Bluetooth receiver circuitry in the cellular telephone 916, and transmitted to the individual at the other end of the line using one of the many cellular telephone connection protocols (e.g., CDMA). As discussed above, when the individual at the other end of the line is speaking, that speech is transmitted from the Bluetooth transmitter circuitry in cellular telephone 916 to Bluetooth transceiver 923 (FIG. 9A), which signal is then sent over the bus for ultimate reproduction over speakers 911.

Further disclosed in FIG. 9B are portable GPS device 986 and wireless internet receiver 988, both of which are coupled to portable Bluetooth transceiver 990. The GPS device 986 may, under user control, transmit a visual signal to LCD display 996 or television display 994, in a manner previously described. Wireless internet receiver 988 is any device configured to receive, over a long-range network, wireless internet access. The data received may also be sent via portable Bluetooth transceiver to the LCD display 996, for example, and the user may use a user interface on the vehicle dashboard (not shown) or portable remote control 978 to interactively access the internet in the vehicle.

Equalizer 953, along with transmitter 904, provides optional equalization functions for controlling the quality of audio transmitted over the bus. The use of equalizer 953 is controlled by the bus arbitrator 914 (FIG. 9B).

FIG. 9B also shows memory 955 coupled to TX/RX unit 906. This memory is used in conjunction with the bus arbitrator 914 (FIG. 9A) for allocating bandwidth on the bus to various devices, and for controlling operations on the bus. A memory controller (not shown) may additionally be present to perform reads and writes of data in the memory 955.

Shown further in FIG. 9B is satellite radio receiver 967, integrated into the bus of the vehicle. The satellite radio transmits its data to a digital signal processor 957 (and, in cases where the incoming signal is analog, an ADC may also be employed). DSP 957 performs any necessary sampling or conversion of the signal, which is then sent to amplifier 963 for transmission over the bus. (Note that the TX unit is not shown here). Thereupon, the satellite audio transmission can be reproduced over speakers 111 (FIG. 9A) under the control of a vehicle occupant, using an appropriate user interface or satellite radio controls built into the stereo head unit of the vehicle.

In addition, flash interface 969 may be integrated into the vehicle. The flash interface 969 allows a user to insert flash memory cards into a slot located on the dashboard, or other suitable area in the vehicle's interior. Audio and video can be recorded onto the flash memory by a source device. For example, where the source device is satellite radio receiver 967, the address of the flash interface can be appended to the audio data, and the data can then be sent to the flash interface for recordation on the flash media. As another illustration, a user can speak into microphone 984, which produces a signal that can be passed onto the bus in the manner described above, and addressed to the flash memory for recordation.

In addition, a vehicle-integrated DVD/CD player may be coupled to the bus via encoder/modulator 998, amplifier 908, and transmitter 904 for transmission of CD music to speakers 911 in the manner described above, or for transmission to both speakers 911 and either television display 944 or LCD display 996.

The previous description is provided to enable any person skilled in the art to practice the various embodiments described herein. Various modifications to these embodiments will be readily apparent to those skilled in the art, and the generic principles defined herein may be applied to other embodiments. Thus, the claims are not intended to be limited to the embodiments shown herein, but is to be accorded the full scope consistent with the language claims, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A wireless audio source for transmitting audio content to a receiver coupled to a host bus integrated into a vehicle, comprising:
a wireless transmitter module configured to interface with an output of a portable audio player, to receive an audio signal from the portable audio player, and to wirelessly transmit the audio signal using a predetermined wireless protocol;
wherein the transmitted audio signal is received by a wireless receiver coupled to an interface with the host bus for transmitting the audio data onto the bus, and wherein the wireless receiver is configured to receive the transmitted audio signal using the predetermined wireless protocol and to recover audio data in the signal for playback on speakers in the vehicle.

2. The wireless audio source of claim 1 wherein the predetermined wireless protocol is Bluetooth.

3. The wireless audio source of claim 1 wherein the wireless receiver sends, through the host bus, the audio data to the speakers, the speakers configured to electronically interface with the host bus for audio reproduction in the vehicle.

4. The wireless audio source of claim 1 wherein the portable audio player is configured to play music using an MPEG1 layer 3 protocol.

5. The wireless audio source of claim 1 wherein a plurality of multimedia devices are configured to interface with the host bus.

6. The wireless audio source of claim 1 wherein the host bus further comprises a bus controller and memory for arbitrating control over the bus, and a radio and speakers, the radio and speakers coupled to respective interfaces to the bus, and wherein a user can control the volume and settings associated with the sound derived from the transmitted audio signal by using the radio controls.

7. A wireless audio source integrated into a host bus of a vehicle, comprising:
a transmitter module comprising one or more input jacks for receiving an audio signal from a portable audio player, circuits for converting the audio signal into a first format suitable for wireless transmission, and an antenna for transmitting the first formatted audio signal using a predetermined wireless protocol; and
a receiver module connected to the host bus and comprising an antenna for receiving the first formatted audio signal and circuits for converting the first formatted audio signal into a second format suitable for transmitting data in the first formatted audio signal into a second format for transmission onto the host bus.

8. The wireless audio source of claim 7 wherein the receiver module is configured to transmit the second formatted audio signal onto the bus for playback by speakers in the vehicle.

9. The wireless audio source of claim 7 wherein the predetermined wireless protocol comprises an I.E.E.E. 802.11 protocol.

10. The wireless audio source of claim 7 wherein the predetermined wireless protocol comprises a Bluetooth protocol.

11. The wireless audio source of claim 7 further comprising a controller and memory connected to the bus, the controller and memory configured to arbitrate signals on the bus and to send and receive messages to and from a radio connected to the bus, the messages comprising information for enabling a user of the radio to control volume of audio content sent by the receiver module to speakers in the vehicle.

12. The wireless audio source of claim 7 wherein the receiver module transmits and receives signals to and from the radio over a control channel for enabling a user of the radio to control volume and settings associated with playback of audio content on speakers in the vehicle.

13. The wireless audio source of claim 7 wherein the receiver module transmits the second formatted audio signal to one or more multimedia devices interfaced with the host bus.

14. The wireless audio source of claim 7 wherein the receiver module transmits the second formatted audio signal to an equalizer interfaced with the host bus.

15. The wireless audio source of claim 7 wherein the receiver module transmits the second formatted audio signal to digital recording means interfaced with the host bus.

16. The wireless audio source of claim 7 wherein the receiver module is integrated into the vehicle.

17. The wireless audio source of claim 7 wherein the receiver module and transmitter module are integrated into the vehicle.

18. The wireless audio source of claim 7 wherein the portable audio source comprises an MPEG 1 layer 3 player.

19. A wireless audio source integrated with a host bus of a vehicle, comprising:
wireless transmitter means for transmitting an audio signal from a portable audio player to a receiver module;
wireless receiver means for transmitting the audio signal to the host bus; and
playback means for reproducing the audio content over speakers in the vehicle.

20. The wireless audio source of claim 19 wherein the wireless transmitter means and wireless receiver means use a Bluetooth protocol for wirelessly transmitting and receiving the audio signal.

21. The wireless audio source of claim 19 further comprising radio control means for enabling a user to control settings associated with the reproduction of the audio content from a radio in the vehicle.

22. A method for reproducing audio on speakers in a vehicle using signals transmitted over a host bus in the vehicle, comprising:
(a) wirelessly transmitting, from a transmitter module, audio content received from a portable audio player connected to the transmitter module;
(b) wirelessly receiving, from the transmitter module, the audio content at a receiver module;
(c) transmitting, over a bus interface of a host bus in the vehicle, a signal comprising the audio content onto the bus, the signal addressed to nodes coupled to respective interfaces of speakers on the bus; and
(d) reproducing the audio content over the speakers.

23. The method of claim 22 wherein the portable audio player comprises an MPEG 1 layer 3 player.

24. The method of claim 22 wherein the wireless transmitter and wireless receiver are configured to communicate using a Bluetooth protocol.

25. The method of claim 22 wherein the wireless receiver comprises an integrated interface controller.

26. The method of claim 22 wherein the wireless receiver is integrated into the vehicle.

27. The method of claim 22 further comprising the steps of:
transmitting and receiving, to and from the wireless receiver, signals to and from a radio in the vehicle, to enable a user to control settings associated with the reproduction of audio content from the radio controls.

28. A wireless apparatus for enabling a portable media device to communicate with a device connected to a host bus integrated into a vehicle, comprising:
a first portable wireless transceiver configured to connect with the portable media device using a wired connection; and
a second wireless transceiver coupled, using a wired connection, to an interface on the host bus; wherein:
the first portable wireless transceiver receives data from the portable media device and sends the data comprising an address of the device, using a short-range wireless protocol, to the second wireless transceiver; and wherein:
the second wireless transceiver receives the data using the short-range wireless protocol and transmits it onto the bus to the device.

29. The wireless apparatus of claim 28 wherein the short-range wireless protocol comprises a Bluetooth standard.

30. The wireless apparatus of claim 28 wherein the portable wireless transceiver comprises a universal serial port interface for connecting with the portable media device.

31. The wireless apparatus of claim 28 wherein the portable media device comprises a laptop computer.

32. The wireless apparatus of claim 28 wherein the first portable wireless transceiver comprises a central processing unit, memory circuits, digital logic circuits, a wireless transmitter, wireless receiver, and an antenna.

33. The wireless apparatus of claim 28 wherein the short-range wireless protocol comprises an I.E.E.E. 802.11 (n) standard.

34. The wireless apparatus of claim 28 wherein the first portable wireless transceiver transmits data to the portable media source.

35. The wireless apparatus of claim 28 wherein the second wireless transceiver wirelessly transmits data received from the device over the host bus to the first portable wireless transceiver.

36. The wireless apparatus of claim 28 wherein the device is coupled to the host bus using a second interface.

37. The wireless apparatus of claim 28 wherein the device comprises a visual display mounted in the vehicle.

38. The wireless apparatus of claim 28 wherein the first wireless portable transceiver further comprises a remote control, and the device comprises a vehicle security system, wherein the remote control is configured to communicate with the vehicle security system.

39. A portable wireless apparatus for controlling devices wired to a host bus of a vehicle, comprising:
a portable remote control comprising a first wireless transceiver configured to transmit and receive data to and from a second wireless transceiver coupled to an interface on the host bus; wherein
the second wireless transceiver is configured to transmit first signals received wirelessly from the first wireless transceiver to one or more of the devices, and wherein the second wireless transceiver is configured to wirelessly transmit second signals received from at least one of the devices to the first wireless transceiver.

40. The portable wireless apparatus of claim 39 wherein the data transmitted from the first wireless transceiver comprises an address of at least one of the devices.

41. The portable wireless apparatus of claim 39 wherein the second signals comprise data comprising an address of the portable remote control.

42. The portable wireless apparatus of claim 39 wherein a first one of the devices comprises a vehicle security system.

43. The portable wireless apparatus of claim 39 wherein a second one of the devices comprises a vehicle door lock and unlock controller.

44. The portable wireless apparatus of claim 39 wherein a third one of the devices comprises a vehicle window controller.

45. The portable wireless apparatus of claim 39 wherein a fourth one of the devices comprises a display mounted in the vehicle.

46. The portable wireless apparatus of claim 39 wherein a fifth one of the devices comprises a moon roof controller.

47. The portable wireless apparatus of claim 39 wherein the first and second wireless transceivers are configured to transmit and receive the first and second signals using a Bluetooth protocol.

48. The portable wireless apparatus of claim 39 wherein the first and second wireless transceivers are configured to transmit and receive the first and second signals using an I.E.E.E. 802.11 protocol.

49. The portable wireless apparatus of claim 39 wherein the first and second wireless transceivers are configured to transmit and receive the first and second signals using an I.E.E.E. 802.11(n) protocol.

50. The portable wireless apparatus of claim 39 wherein the first and second wireless transceivers are configured to transmit and receive the first and second signals using an Ultra-Wideband protocol.

51. A system for wirelessly communicating with devices coupled to a vehicle host bus, comprising:
first transceiver means for wirelessly transmitting first signals comprising first data and for wirelessly receiving second signals comprising second data;
second transceiver means for wirelessly transmitting the second signals comprising the second data to the first transceiver means and for wirelessly receiving first signals comprising first data from the first transceiver means;
host bus interface means for connecting the devices to the host bus; and
device communication means for transmitting third signals comprising third data over the host bus to the second transceiver means, and for receiving fourth signals comprising fourth data over the host bus from the second transceiver means.

52. The system of claim 51 wherein the first and second transceiver means are configured to use a Bluetooth wireless protocol.

53. The system of claim 51 wherein the first and second transceiver means are configured to use an I.E.E.E. 802.11 wireless protocol.

54. The system of claim 51 wherein the first and second transceiver means are configured to use an Ultra-Wideband wireless protocol.

55. The system of claim 51 wherein at least one of the devices comprises a multimedia device.

56. The system of claim 51 wherein at least one of the devices comprises a vehicle security system controller.
